(19) United States
(12) Patent Application Publication
(10) Pub. No.: US 2004/0201040 A1
(43) Pub. Date: Oct. 14, 2004

(54) Electronic device

(76) Inventors: Tsuyoshi Fujihara, Kawasaki (JP); Tatsuya Usuki, Kawasaki (JP); Shozo Fujita, Kawasaki (JP); Isao Saito, Kyoto (JP)

Correspondence Address: ARMSTRONG, KRATZ, QUINTOS, HANSON & BROOKS, LLP, 1725 K STREET, NW, SUITE 1000, WASHINGTON, DC, 20006, US

(21) Appl. No.: 10/768,180

(22) Filed: Feb. 2, 2004

(30) Foreign Application Priority Data
Feb. 3, 2003 (JP) 2003-26334(PAT)

(51) Int. Cl. H01L 31/109

(52) U.S. Cl. 257/200

(57) ABSTRACT

An electronic device which comprises one or more functional elements consisting of a high molecular weight material which has a steric structure containing one or more three-dimensionally disposed modifying functional groups, the steric structure on the high molecular weight material being known or predictable. In the electronic device, the high molecular weight material is a biopolymer, a synthetic polymer or a combination thereof, and the modifying functional groups are selected from the group consisting of positive hole-transporting functional groups, electron-transporting functional groups and a combination thereof. The electronic device includes a wide variety of devices such as diodes such as photodiodes and light-emitting diodes, capacitors, resistors and transistors such as bipolar transistors and FETs (field effect transistors).

### CROSS-REFERENCE TO RELATED APPLICATIONS

This application is based on and claims a priority of Japanese Patent Application No. 2003-26334, filed on Feb. 3, 2003, the contents being incorporated herein by reference.

### BACKGROUND OF THE INVENTION

1. Field of the Invention

The present invention relates to an electronic device, more particularly, an electronic device having a size of nanometer order, i.e., nanostructured electronic device which is also called “nanodevice”. In particular, the present invention is a nanostructured electronic device containing one or more functional elements incorporated into the device by utilizing a stereostructure or steric structure of the high molecular weight material or briefly high polymer such as DNA (deoxyribonucleic acid).

2. Description of the Related Art

Recently, there have been suggested and tried to produce molecular electronic devices using electrically conductive organic molecules (see, for example, Baer and Neuhauser, Phase Coherent Electronics: A Modular Switch Based on Quantum Interference, J. Am. Chem. Soc., Vol. 124, No. 16, P4200-4201, 2002). However, the conductive organic molecules suffer from the problems that in proportion to the size of the organic molecules and as a function of the degree of the activation of the molecules, insufficient orientation and duplication of the molecules are produced, thereby an amplification of the electric current can be reduced and a switching speed of the devices can be retarded in the resulting molecular electronic devices. These problems can be solved if the organic molecules used have a relatively small molecular size. However, such a small size of the organic molecules can cause another problem concerning the structure of the resulting molecular electronic devices. That is, if the organic molecules having a relatively small size are used in the production of the devices, a structure of the resulting molecular electronic devices is limited to the specific one and thus it is difficult to produce a wide variety of molecular electronic devices depending upon desires. In addition to this problem, it is necessary for use of the small-sized organic molecules to produce the electrodes for immobilization of such molecules by using highly sophisticated technologies. It is therefore in practice that use of the small-sized organic molecules in the production of the molecular electronic devices has less expansibility.

Alternatively, there have been suggested to use electrically conductive polymers which are free of the above-described problems, in place of the small-sized organic molecules, in the production of the molecular electronic devices. The conductive polymers used herein are preferably those having the structure which is already known or can be easily predicted, because such a structure enables to easily design the molecular electronics and also provide other advantages. The polymers whose steric structure is already known include, for example, biopolymers of the known structure such as proteins and others. Among the well-known biopolymers, DNA (deoxyribonucleic acid) is the most interesting polymer and thus it is widely studied in the field of molecular electronics, because DNA has both of a complementary double helix structure and an electrical conductivity (see, for example, Boon and others, “Mutation Detection by Electrocatalysis at DNA-modified Electrodes”, Nature Biotechnology, Vol. 18, P1096-1100, October 2000).

### SUMMARY OF THE INVENTION

The inventors of the present invention have conducted intensive studies for solving the prior art problems described above, and have found that a novel nanostructured electronic device which can eliminate the above-discussed problems which could not be solved by the prior art electronic devices, if a high molecular weight material having a stereostructure or steric structure (three-dimensional structure) which is already known or can be easily predicted, is used in the production of functional elements or parts in the electronic devices, and at the same time, one or more modifying functional groups suitably selected are three-dimensionally disposed in the steric structure as a template.

According to the present invention, there is provided an electronic device which comprises, fabricated thereon and/or therein, one or more functional elements consisting of a high molecular weight material which has a steric structure containing one or more three-dimensionally disposed modifying functional groups, the structure being known or predictable, in which

the high molecular weight material is a biopolymer (biological polymer), a synthetic polymer or a combination thereof, and

the modifying functional groups are selected from the group consisting of positive hole-transporting functional groups, electron-transporting functional groups and a combination thereof.

In the electronic device of the present invention, since the high molecular weight material (hereinafter, briefly referred to “polymer”) is used in the formation of the functional elements and the polymer itself can bear specific information, any desired electronic devices can be produced with the desired connection of the functional elements as was designed, and ultimately integral circuits having a nano-sized structure and self-organized constitution can be produced.

Further, since the polymer used in the formation of the functional elements is particularly modified with a hole-transporting or electron-transporting functional group, an electrical resistance of the functional elements can be lowered and also application of an electric current to between the adjacent functional groups enables to provide an increased stability in the resulting electronic device.

### BRIEF DESCRIPTION OF THE DRAWINGS

FIG. 1 is a schematic view showing a bipolar transistor produced in Example 1;

FIG. 2 is a schematic view showing a photodiode produced in Example 2;

FIG. 3 is a cross-sectional view schematically showing a part of the transistor produced in Example 3; and

FIG. 4 is a graph plotting the results obtained upon modification of gold electrodes in Example 3.

### DESCRIPTION OF THE PREFERRED EMBODIMENTS

The electronic device of the present invention has a miniaturized structure, and thus it can be called a “nanostructure”. That is, the electronic device has a size in the order of nanometers (nm) because of the size of the polymer such as DNA constituting the device. A size of the electronic device can be varied depending on the type and size of the polymers used, but generally it is not more than about 300 nm, preferably in the range of about 3 to 100 nm. Generally speaking, it is preferred that the electronic device is as miniaturized as possible.

Further, the electronic device of the present invention is novel, and also it can be advantageously used in place of a wide variety of conventional electronic devices. Generally, the electronic device of the present invention comprises a substrate and one or more functional element fabricated in any optional pattern on the substrate, although any modifications including use of additional elements, parts and others may be applied to the device.

In the electronic device, the substrate used therein is not restricted to the specific substrate material. For example, the substrate may be any semiconductor substrate such as silicon substrate and the like. If necessary, the substrate may be formed from any other materials such as glass, or it may be a circuit board and the like.

The functional element means any element or part which can contribute a specific function or effect to the resulting electronic device when used in the formation of the device. The functional element can be used in any desired form such as wire and plate, and preferably it can be used as an electrically conducting wire. Suitable examples of the functional element used in the practice of the present invention include, but are not restricted to, circuits, resistors, diodes such as photodiode and light-emitting diode, capacitors, transistors such as bipolar transistor and field effect transistor (FET) and others. These functional elements may be used alone or in combination of two or more elements. Further, they may be applied or produced in a surface portion and/or internal portion of the substrate. Of course, these functional elements may be used in combination with any additional functional elements, if desired.

The functional element used in the present invention has a steric structure. The steric structure should be known to any producers for the functional elements and others, or the steric structure should be easily determined or predicted by a person skilled in the art, based on the information of the functional element or the functional element-providing material. Further, the functional element has one or more three-dimensionally disposed modifying functional groups in any desired positions in the steric structure.

Suitable polymers for the formation of the functional element is not restricted to the specific one, if the polymers can satisfy the above requirements concerning the steric structure and the modifying functional groups. Suitable polymers include both of biopolymers and synthetic polymers. These polymers may be used alone or in combination of two or more polymers.

Examples of the biopolymers useful in the practice of the present invention include, but are not restricted to, DNA (deoxyribonucleic acid), RNA (ribonucleic acid), a hybrid of DNA and RNA, proteins, saccharides and a complex thereof. If desired, the biopolymers may be used as a composite of the biopolymers such as DNA-RNA hybrid.

In the practice of the present invention, DNA can be particularly advantageously used in the formation of the functional elements, although DNA generally has the drawback that an electric current cannot be applied and passed due to the large resistance. This is because according to the present invention, such drawback can be omitted by the application of functional groups, particularly the specific functional groups capable of transporting positive holes or electrons, to DNA. Further, DNA can largely contribute to the miniaturization of the electric devices, because it can form a pn junction in a very small site of the device because of its excellent selectivity in the orientation. Furthermore, since it has a self organization function and thus can automatically fabricate a circuit or other elements, DNA enables to easily and optionally produce electronic devices depending upon the desired design pattern of the device. Especially, DNA is worthful in the production of electronic devices, because using DNA as the functional element-providing material, it enables to freely design and produce the electronic devices having the three-dimensionally distributed structure.

In place of or in combination of the biopolymers described above, any synthetic polymer may be used as a functional element-providing material. The synthetic polymer useful in the practice of the present invention is a synthetic polymer capable of forming double strands while selectively controlling the orientation. Suitable examples of the synthetic polymer includes, but are not restricted to, peptide DNA, guanidine DNA and others. If desired, these synthetic polymers may be used in the form of a composite of the polymers.

In the electronic device of the present invention, to give a nanostructure to the device, it is necessary to use DNA or other polymers as a template of the device to thereby three-dimensionally introduce and dispose modifying functional groups. As the functional groups, it is preferred to use a functional group capable of easily transporting positive holes (hole-transporting functional group) or a functional group capable of easily transporting electrons (electron-transporting functional group). This is because for example, if these functional groups are introduced into the polymers constituting the functional element of the device, an electric resistance of the functional element can be lowered and a stability of the device can be improved upon application of an electric current between these functional groups. The hole-transporting functional group and the electron-transporting functional group each may be used alone or in combination of two or more groups.

The hole-transporting functional group useful in the practice of the present invention includes various hole-transporting groups. Typical examples of the useful hole-transporting functional group include, but are not restricted to, those originated from TPAC (1,1-bis[4-[N,N′-di(p-tolyl)amino]phenyl]cyclohexane), TPD (N,N′-diphenyl-N,N′-di(m-tolyl)benzidine) represented by the following formula:

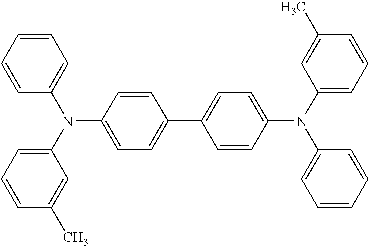

, phenothiazine represented by the following formula:

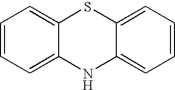

and other hole-transporting compounds. Other suitable hole-transporting functional groups include those originated from TTF (tetrathiafulvalene) represented by the following formula:

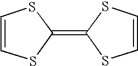

, fullerene such as fullerene C60, and others.

These hole-transporting functional groups may be introduced in different concentrations and distributions into DNA and other polymers. Depending on the desired structures, functions and characteristics of the electronic devices, it is preferred that the most preferred hole-transporting functional group is selected and disposed in a predetermined position of the polymer.

Further, the electron-transporting functional group useful in the practice of the present invention includes various electron-transporting groups. Typical examples of the useful electron-transporting functional group include, but are not restricted to, those originated from BND (2,5-bis(1-naphtyl)-1,3,4-oxadiazole), PBD (2-(4-tert-butylphenyl)-5-(4-biphenyl)-1,3,4-oxadiazole) represented by the following formula:

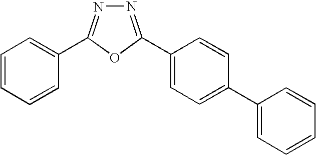

, anthraquinone represented by the following formula:

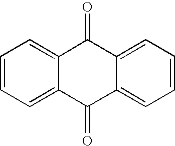

and other electron-transporting compounds. Other suitable electron-transporting functional groups include those originated from TCNQ (tetracyanoquinodimethane) represented by the following formula:

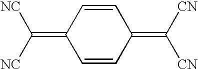

, porphyrin such as 21H, 23H-porphyrin represented by the following formula:

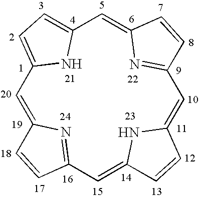

, metal complexes and others.

As in the hole-transporting functional groups described above, these electron-transporting functional groups may be introduced in different concentrations and distributions into DNA and other polymers. Depending on the desired structures, functions and characteristics of the electronic devices, it is preferred that the most preferred electron-transporting functional group is selected and disposed in a predetermined position of the polymer. Alternatively, to obtain additional effects in addition to the effects based on the sole use of the hole-transporting functional groups or the electron-transporting functional groups, the hole-transporting functional groups and the electron-transporting functional groups may be used in combination.

In the electronic device of the present invention, the functional element to be included in the device includes a variety of functional elements, preferably an electrically conductive wire. This is because the conductive wire can be constituted from any polymers having the specific structure.

The conductive wire can be produced using different methods. For example, the conductive wire can be produced by introducing into the selected polymer such as a biopolymer, a synthetic polymer or a combination thereof, for example, DNA, a hole-transporting functional group such as TPAC or TPD and/or a electron-transporting group such as BND or PBD, in a periodic manner (for example, per three residual groups). Introduction of the functional groups can be carried out using the conventional methods.

The conductive wire as produced in accordance with the above-described manner can be used as a circuit component without further processing. Alternatively, when the conductive wire is produced in accordance with the above manner, an introduction density of the modifying functional groups may be changed to vary a resistivity of the wire depending on the change of the density. The thus obtained conductive wire can be utilized as a resistor.

Further, in place of use of a single conductive wire, two or more conductive wires may be used in combination. For example, two or more conductive wires having different characteristics can be connected in series to form a combined conductive wire in the form of a block polymer. The resulting conductive wire can be utilized as a diode.

Furthermore, different types of the diodes can be easily produced by changing the above-described production process of the conductive wire.

In one preferred embodiment of the present invention, a photodiode can be produced as a variation of the diode. The photodiode can be produced, for example, by introducing in a conjunction portion of the diode a functional group capable of controlling a discharge or inclusion of electrons by its optical response, for example, ZnPBO and the like, or other functional groups to form the intended block polymer.

In another preferred embodiment of the present invention, a light-emitting diode can be produced as a variation of the diode. The light-emitting diode can be produced, for example, by introducing in a conjunction portion of the diode a functional group capable of generating light emission by its electromotive force, for example, tris(8-quinolinorat)aluminum complex and bis(benzoquinolinorat)beryllium complex, each being represented by the following formula, or other functional groups to form the intended block polymer. Tris(8-quinolinorat)aluminum complex:

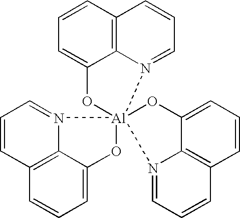

Bis(benzoquinolinorat)beryllium complex:

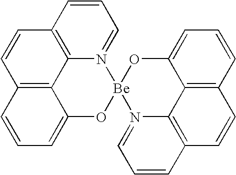

Moreover, the conductive wire can be utilized as a capacitor. For example, the capacitor can be produced by insulating the resulting conductive wire. Insulation can be generated by changing at least a part of the segments of the conductive wire to obtain a double-strand DNA, a single-strand DNA or DNA having the mismatched arrangement, each having no modifying functional group. In this insulation process, to reinforce the structure of the resulting capacitor, any protein capable of specifically bonding to the generated insulating arrangement may be added to the wire. Next, a block polymer having a condition capable of being easily electrically charged is produced in a neighborhood of the insulating arrangement. For example, this process can be easily carried out by changing a density of one or more modifying functional groups such as functional groups having different polarities positioned in a neighborhood of the insulating arrangement. As a result of such a series of the processing steps, a conductive wire effective as a capacitor can be produced.

In addition to the above applications, the conductive wire also can be utilized as a transistor such as bipolar transistor or field effect transistor (FET). For example, the bipolar transistor can be produced by alternately connecting three conductive wires having different characteristics in series to form a PNP or NPN junction. Then, a biopolymer and/or a synthetic polymer such as DNA is branched from a central segment of the PNP or NPN junction. The thus obtained block polymer having the conductive wires connected to each other can be utilized as a bipolar transistor.

Similarly, a FET can be produced from the conductive wire. For example, the FET can be produced from the conductive wire in such a manner that the conductive wire acting as the FET has an electrical output capable of being controlled by applying a predetermined level of the electric field to the FET from an outside thereof.

### EXAMPLES

The present invention will be further described with reference to the embodiments thereof. However, it should be noted that the present invention should not be restricted to these embodiments.

As DNA and other biopolymers generally have a high electrical resistance, it is difficult to directly incorporate such biopolymers into the molecular electronics. This is because the DNA or other biopolymers have a tendency of being subjected to an oxidative damage upon application of an electric power to the devices. In fact, these biopolymers are not satisfactory for the practical use in the field of the molecular electronics.

So, it is an object of the present embodiments to provide an electronic device which is included in the scope of the so-called “molecular electronics”, has a size of nanometer(nm) order and a simplified structure, can be easily produced, and has a low electrical resistance (resistivity) and stable characteristics.

It is another object of the present embodiments to provide an electronic device which design can be changed at a high level of freedom depending upon desires and other factors, thereby enabling to produce any electronic devices as is designed.

It is still another object of the present embodiments to provide an electronic device in which functional elements constituting the device can be produced by using DNA or other biopolymers.

### Example 1

In this example, the bipolar transistor schematically illustrated in FIG. 1 was produced. In the illustrated bipolar transistor, three types of electrodes: Electrodes 1, 2 and 3 were disposed at a distance of about 15 nm, in which Electrode 1 is a source, Electrode 2 is a drain, and Electrode 3 is a gate. To each of the electrodes, three types of DNAs 1, 2 and 3 were selectively immobilized. DNA 1 was immobilized to Electrode 1, and similarly DNAs 2 and 3 were immobilized to Electrodes 2 and 3, respectively. The DNAs 1, 2 and 3 used in this example are the following DNA 48 mers.

DNA 1:
HS(CH₂)₆ₚCT¹G-CAT-GAT-GT¹A-GT¹G-CT¹G-GT¹A-CAC-
GT²C-TAC-AAC-GT²G-CAC-TT²T-GT²T-CAC
DNA 2:
HS(CH₂)₆ₚGT¹G-AAC-AAA-GT¹G-CAC-GT¹T-GT¹A-GAC-
GAT-AT²C-CAG-TT²A-GAT-CT²C-GAA-CT²A
DNA 3:
HS(CH₂)₆ₚTAG-TT²C-GAG-AT²C-TAA-CT²G-GAT-AT²C-
GTG-AT¹C-CAG-CAC-TAC-AT¹C-AT¹G-CAG

In this bipolar transistor, the modifying nucleic acids having different polarities, described in the above paragraph entitled “DESCRIPTION OF THE PREFERRED EMBODIMENTS”, were introduced as T¹ and T² of the DNAs. It was observed that the resulting bipolar transistor can exhibit the expected transistor effects.

### Example 2

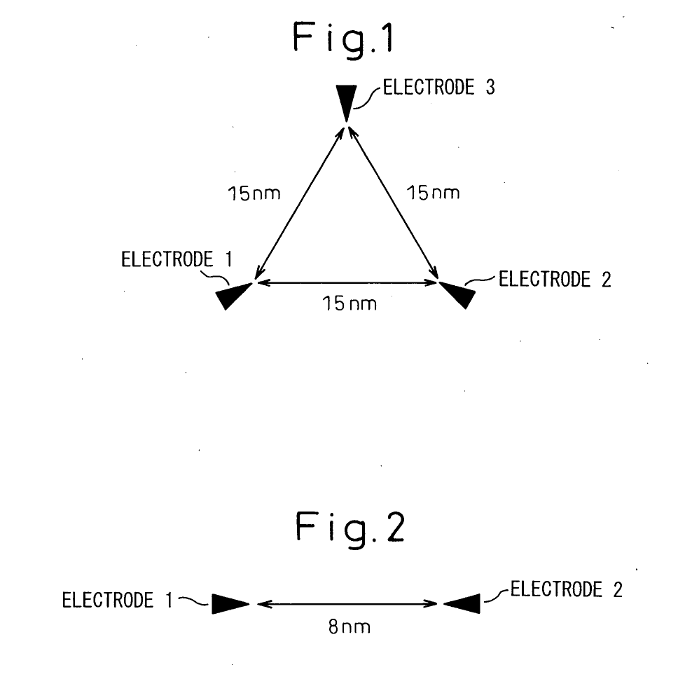

In this example, the photodiode schematically illustrated in FIG. 2 was produced. In the illustrated photodiode, two types of electrodes: Electrodes 1 and 2 were disposed at a distance of about 8 nm. DNAs 1 and 2 were selectively immobilized to Electrodes 1 and 2, respectively. The DNAs 1 and 2 used in this example are as follows.

DNA 1:
HS(CH₂)₆ₚCT¹C-CAT-GAT-GT²A-GT²G-GT³A-CAC
DNA 2:
HS(CH₂)₆ₚGAG-TAC-CAG-CAC-TAC-AT¹C-AT¹G-CAG

In this photodiode, the modifying nucleic acids having different polarities, described in the above paragraph entitled “DESCRIPTION OF THE PREFERRED EMBODIMENTS”, were introduced as T¹ and T³ of the DNAS, and at the same time, a nucleic acid modified with a functional group capable of emitting light upon application of an electromotive force was introduced as T² of the DNA. It was observed that the resulting photodiode can exhibit the expected photodiode effects.

### Example 3

In this example, the effects obtained when the polymer having the steric structure is modified with the specific functional group were confirmed. Note in this example that DNA which is a typical example of the biopolymer was used as a sample polymer.

[Synthesis of DNAS]

Five types of the DNAs described below were synthesized using the DNA synthesizer commercially available from Applied Co. The staring materials are as follows.

DNA 32mers:
5′-HS(CH₂)₆ₚGATCACTAGAAAGACTACGATGATTACGACTA-
3′ (hereinafter, referred to as HS32)
DNA 8mers:
5′-T*AGT*CGT*A-3′
(hereinafter, referred to as DNA 5′-1)
DNA 12mers:
5′-AT*CAT*CGT*AGT*C-3′
(hereinafter, referred to as DNA 5′-2); and
5′-TT*TCT*AGT*GAT*C-3′
(hereinafter, referred to as DNA 5′-3)

Note in these DNAs that T* is represented by the following formula:

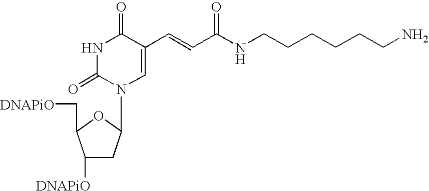

Alternatively, although it was not used in this example, the following compound may be used as T* of the DNAS.

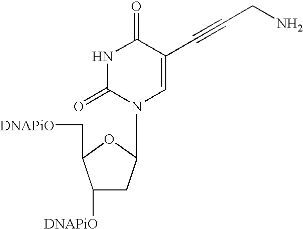

Next, the DNA 5′-1 was reacted with ferrocene isocyanate in a aqueous solution to synthesize Fe-5′-1. The product was then purified.

Similarly, the DNA 5′-2 was reacted with TPD isocyanate represented by the following formula:

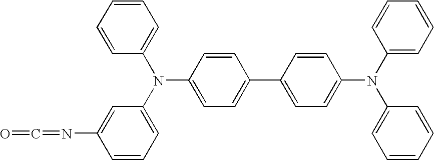

in an aqueous solution to synthesize TPD-5′-2. The product was then purified.

Further, the DNA 5′-3 was reacted with TPD isocyanate in an aqueous solution to synthesize TPD-5′-3. The product was then purified.

Further, the DNA 5′-2 was reacted with PBD isocyanate represented by the following formula:

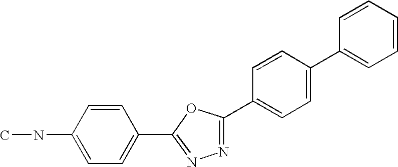

in an aqueous solution to synthesize PBD-5′-2. The product was then purified.

Furthermore, the DNA 5′-3 was reacted with PBD isocyanate in an aqueous solution to synthesize PBD-5′-3. The product was then purified.

The presence of the functional group in the predetermined site of the structure could be confirmed in each of the DNA derivatives produced in the above processes. Note that the introduction of the functional group is based on the following reaction schema.

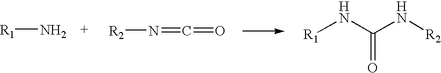

[Evaluation Test]

The DNA (HS32) and the DNA derivatives (Fe-5′-1, TPD-5′-2, TPD-5′-3, PBD-5′-2 and PBD-5′-3) were combined under the different conditions as shown in the following Table 1 to prepare different block polymers. In the conditions of Table 1, “yes” means that the DNA or its derivative can satisfy the captioned condition, while “no” means that the DNA or its derivative can not satisfy the captioned condition. That is, as is appreciated from Table 1, the block polymers which can satisfy the Condition 1 may have the structure . . . (HS32)(Fe-5′-1)(TPD-5′-2)(PBD-5′-3).

TABLE 1

| | Condition | Condition | Condition | Condition |
|---|---|---|---|---|
| | 1 | 2 | 3 | 4 |
| HS32 | yes | yes | yes | yes |
| Fe-5′-1 | yes | yes | yes | yes |
| TPD-5′-2 | yes | no | no | yes |
| PBD-5′-2 | no | yes | yes | no |
| TPD-5′-3 | no | yes | no | yes |
| PBD-5′-3 | yes | no | yes | no |

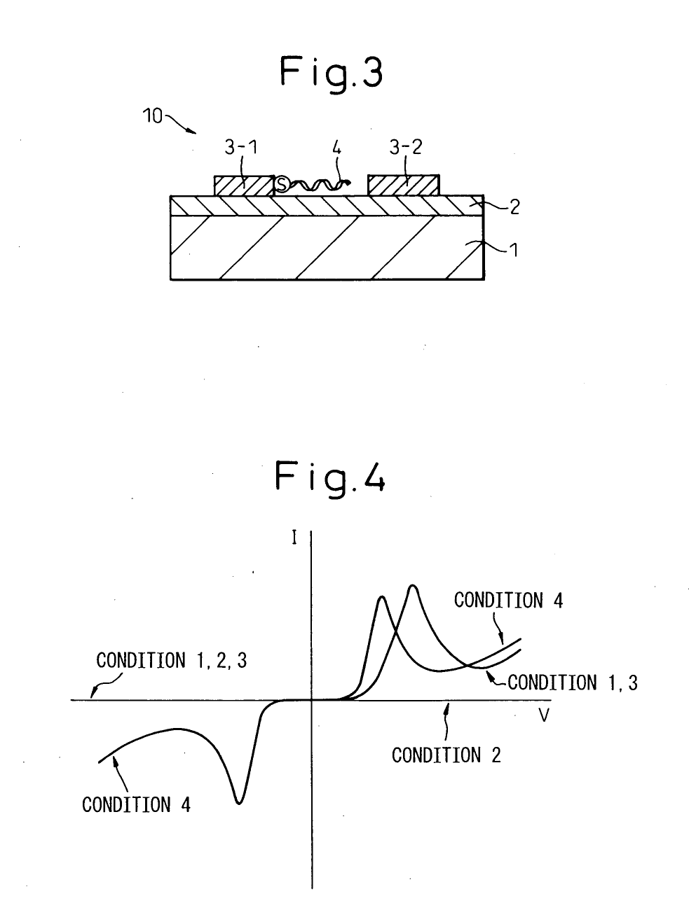

Next, total 4 types of the block polymers (Conditions 1 to 4) each was incorporated into a transistor 10, a part of which is schematically illustrated in FIG. 3, to form a wiring circuit 4 consisting of a conductive wire. The circuit 4 was applied onto a silicon substrate 1 having an insulating layer (silicon oxide layer) 2 on a surface thereof to connect it to the gold electrode (source) 3-1 already formed on the substrate 1. The reference numeral 3-2 means a gold electrode (drain). A distance between the gold electrodes 3-1 and 3-2 was about 10 nm.

In each of the produced transistors, the current application test was carried out to obtain the test results plotted in FIG. 4. As is appreciated from the graph of FIG. 4, when the electric circuit was produced from a conductive wire in accordance with the present invention, it becomes possible to produce a transistor having a lowered electric resistance and also excellent electrical characteristics. Moreover, according to the present invention, the constituting units of the block polymer from which the conductive wire is produced can be freely changed to easily produce the targeted transistor having the desired characteristics without suffering from the difficulty in changing the device design depending on the desires.

As described above, according to the present invention, it becomes possible to provide an electronic device which has a size of nanometer(nm) scale and a simplified structure, can be easily produced, and has a small electrical resistance and stable characteristics.

Further, according to the present invention, it becomes possible to provide an electronic device which design can be changed at a high level of freedom depending upon desires and other factors, thereby enabling to produce any electronic devices as is designed.

Furthermore, in the electronic device of the present invention, there can be obtained remarkable effects that DNA and other biopolymers which could not be used due to the unavoidable problems in the prior art production of the electronic devices can be advantageously used in the formation of functional elements.

1. An electronic device which comprises one or more functional elements consisting of a high molecular weight material which has a steric structure containing one or more three-dimensionally disposed modifying functional groups, said structure being known or predictable, in which
said high molecular weight material is a biopolymer, a synthetic polymer or a combination thereof, and
said modifying functional groups are selected from the group consisting of positive hole-transporting functional groups, electron-transporting functional groups and a combination thereof.

2. An electronic device as defined in claim 1, in which said biopolymer is DNA, RNA, a hybrid of DNA and RNA, proteins, saccharides or a composite thereof.

3. An electronic device as defined in claim 1, in which said synthetic polymer is peptide DNA, guanidine DNA or a composite thereof.

4. An electronic device as defined in claim 1, in which said positive hole-transporting functional group is TPAC, TPD, phenothiazine, TTF or fullerene.

5. An electronic device as defined in claim 1, in which said electron-transporting functional group is BND, PBD, anthraquinone, TCNQ or porphyrine.

6. An electronic device as defined in any one of claims 1 to 5, in which said functional element is an electrically conductive wire.

7. An electronic device as defined in any one of claims 1 to 5, in which said functional element is a circuit consisting of an electrically conductive wire.

8. An electronic device as defined in any one of claims 1 to 5, in which said functional element is a resistor consisting of an electrically conductive wire.

9. An electronic device as defined in any one of claims 1 to 5, in which said functional element is a diode consisting of two or more electrically conductive wires.

10. An electronic device as defined in any one of claims 1 to 5, in which said functional element is a capacitor consisting of two or more electrically conductive wires.

11. An electronic device as defined in any one of claims 1 to 5, in which said functional element is a transistor consisting of two or more electrically conductive wires.

12. An electronic device as defined in any one of claims 1 to 5, in which said functional element is an electrically conductive wire produced upon periodically introducing said positive hole-transporting functional groups and/or said electron-transporting functional groups to said biopolymer and/or said synthetic polymer.

13. An electronic device as defined in claim 12, in which said electrically conductive wire is incorporated therein as a circuit of the device.

14. An electronic device as defined in claim 12, in which said electrically conductive wire is incorporated therein as a resistor, and the resistor has a specific resistance capable of being controlled by varying a density of said modifying functional groups.

15. An electronic device as defined in claim 12, in which said electrically conductive wire is incorporated therein as a diode, and the diode is in the form of a block polymer wherein two or more of said electrically conductive wires are connected in series.

16. An electronic device as defined in claim 15, in which said diode is a photodiode, and said photodiode has introduced in a conjunction portion thereof a functional group capable of controlling a discharge or introduction of electrons by its optical response.

17. An electronic device as defined in claim 15, in which said diode is a light-emitting diode, and said light-emitting diode has introduced in a conjunction portion thereof a functional group capable of generating light emission by its electromotive force.

18. An electronic device as defined in claim 12, in which said electrically conductive wire is incorporated therein as a capacitor, and the capacitor is in the form of a block polymer wherein at least a part of the segments of said electrically conductive wire has an introduced insulating arrangement and said block polymer has a condition capable of being easily electrically charged in a neighborhood of the insulating arrangement.

19. An electronic device as defined in claim 12, in which said electrically conductive wire is incorporated therein as a bipolar transistor, and the bipolar transistor is in the form of a block polymer wherein three of said electrically conductive wires are alternately connected in series to form a PNP or NPN junction and said block polymer has said biopolymer and/or said synthetic polymer branched from a central segment thereof.

20. An electronic device as defined in claim 11, in which said transistor is a field effect transistor, and an electrical output of the field effect transistor can be controlled by applying a predetermined level of the electric field to said device from an outside of said device.
